(19) United States
(12) Patent Application Publication
(10) Pub. No.: US 2006/0063295 A1
(43) Pub. Date: Mar. 23, 2006

(54) Solid-state image pickup device and driving method thereof

(76) Inventor: Kazunobu Kuwazawa, Chino (JP)

Correspondence Address: HARNESS, DICKEY & PIERCE, P.L.C., P.O. BOX 828, BLOOMFIELD HILLS, MI, 48303, US

(21) Appl. No.: 11/214,617

(22) Filed: Aug. 30, 2005

(30) Foreign Application Priority Data
Sep. 22, 2004 (JP) 2004-274619

(51) Int. Cl. H01L 21/00

(52) U.S. Cl. 438/60; 438/76; 438/75

(57) ABSTRACT

A solid-state image pickup device having inside a substrate a plurality of accumulation wells that accumulate light-producing electric charge produced in a photoelectric conversion region corresponding to light applied thereto, the plurality of photoelectric conversion regions being arranged in a two-dimensional matrix on the substrate, including: a plurality of modulation transistors, each of which is provided in every pair of the photoelectric conversion regions adjoined in one direction of the two-dimensional matrix, which control a threshold voltage of a channel using the light-producing electric charge held in a modulation well, and which output a pixel signal corresponding to the light-producing electric charge; a plurality of transfer control elements, each pair of which is provided in every pair of the adjoining photoelectric conversion regions, which shift a potential barrier of a path for transferring the light-producing electric charge between each accumulation well and the corresponding modulation well in the pair of photoelectric conversion regions, and which control the transfer of the light-producing electric charge; and a plurality of transfer gate lines coupled to each of the transfer control elements in the plurality of photoelectric conversion regions arranged in the other direction of the two-dimensional matrix; in that each gate of the plurality of modulation transistors is in a ring-like shape, each gate being provided in a manner that at least a portion of the gate is interposed between partially cut-off portions of every pair of the approximately rectangular photoelectric conversion regions adjoined in one direction of the two-dimensional.

### BACKGROUND OF THE INVENTION

1. Technical Field

The present invention relates to a solid-state image pickup device and a method for driving the same.

2. Related Art

As a solid-state image pickup device mounted on a cellular phone, a digital camera, or the like, there are a charge-coupled-device (CCD) type image sensor (hereinafter referred to as a CCD sensor) and a CMOS type image sensor (hereinafter referred to as a CMOS sensor.)

Further, in recent years, a MOS type solid-state image pickup device (hereinafter referred to as a substrate modulation type sensor) that enables both high image quality and low electric consumption using a threshold voltage modulation method has been proposed (e.g., Japanese Unexamined Patent Publication No. 2002-134729.) In case of the substrate modulation type sensor, a ring gate is used in a modulation transistor. Each of a plurality of sensor cells arranged on a substrate in a two-dimensional matrix includes one ring gate per one photodiode.

However, with the substrate modulation type sensor of the referenced Japanese Unexamined Patent Publication, it is necessary to maintain more than a certain distance between a ring gate and a drain of the modulation transistor in order to maintain the modulation efficiency. Therefore, there is a problem in which the substrate modulation type sensor cannot be miniaturized because the ring gate needs to have more than a certain extent of width.

### SUMMARY

An advantage of the present invention is to provide a solid-state image pickup device that can realize miniaturization of the substrate modulation type sensor by narrowing the cell pitch of the substrate modulation type sensor.

According to an aspect of the invention, a solid-state image pickup device having inside a substrate a plurality of accumulation wells that accumulate light-producing electric charge produced in a photoelectric conversion region corresponding to light applied thereto, the plurality of photoelectric conversion regions being arranged in a two-dimensional matrix on the substrate, includes: a plurality of modulation transistors, each of which is provided in every pair of the photoelectric conversion regions adjoined in one direction of the two-dimensional matrix, which control a threshold voltage of a channel using the light-producing electric charge held in a modulation well, and which output a pixel signal corresponding to the light-producing electric charge; a plurality of transfer control elements, each pair of which is provided in every pair of the adjoining photoelectric conversion regions, which shift a potential barrier of a path for transferring the light-producing electric charge between each accumulation well and the corresponding modulation well in the pair of photoelectric conversion regions, and which control the transfer of the light-producing electric charge; and a plurality of transfer gate lines coupled to each of the transfer control elements in the plurality of photoelectric conversion regions arranged in the other direction of the two-dimensional matrix; in that each gate of the plurality of modulation transistors is in a ring-like shape, each gate being provided in a manner that at least a portion of the gate is interposed between partially cut-off portions of every pair of the approximately rectangular photoelectric conversion regions adjoined in one direction of the two-dimensional.

With such a structure, it is possible to realize the solid-state image pickup device that enables miniaturization of the substrate modulation type sensor by narrowing the cell pitch of the substrate modulation type sensor.

According to another aspect of the invention, a method for driving the solid-state image pickup device having inside a substrate a plurality of accumulation wells that accumulate light-producing electric charge produced in a photoelectric conversion region corresponding to light applied thereto, the plurality of photoelectric conversion regions being arranged in a two-dimensional matrix on the substrate, contains: a plurality of modulation transistors, each of which is provided in every pair of the photoelectric conversion regions adjoined in one direction of the two-dimensional matrix, which control a threshold voltage of a channel using the light-producing electric charge held in a modulation well, and which output a pixel signal corresponding to the light-producing electric charge; a plurality of transfer control elements, each pair of which is provided in every pair of the adjoining photoelectric conversion regions, which shift a potential barrier of a path for transferring the light-producing electric charge between each accumulation well and the corresponding modulation well in the pair of photoelectric conversion regions, and which control the transfer of the light-producing electric charge; and a plurality of transfer gate lines coupled to each of the transfer control elements in the plurality of photoelectric conversion regions arranged in the other direction of the two-dimensional matrix. Each gate of the plurality of modulation transistors is in a ring-like shape, each gate being provided in a manner that at least a portion of the gate is interposed between partially cut-off portions of every pair of the approximately rectangular photoelectric conversion regions adjoined in one direction of the two-dimensional, includes: firstly reading out a noise component from the modulation transistor by controlling a voltage of the gate provided corresponding to the pair of photoelectric conversion regions in one direction of the matrix; transferring the light-producing electric charge from one of the two accumulation wells in the pair of photoelectric conversion regions to the modulation well in one direction of the matrix; and secondly reading out a signal component from the modulation transistor based on the transferred light-producing electric charge by controlling a voltage of the gate provided corresponding to the pair of photoelectric conversion regions in one direction of the matrix.

With such a structure, it is possible to realize the method for driving the solid-state image pickup device that enables miniaturization of the substrate modulation type sensor by narrowing the cell pitch of the substrate modulation type sensor.

### BRIEF DESCRIPTION OF THE DRAWINGS

The invention will be described with reference to the accompanying drawings, wherein like numbers refer to like elements and wherein:

FIG. 1 is a plan view showing a planer configuration of a solid-state image pickup device according to an embodiment of the invention.

FIG. 2 is a cross-sectional diagram taken along an A-A′ line of FIG. 1.

FIG. 3 is a plan view to explain a positional relationship of a ring gate according to the embodiment of the invention.

FIG. 4 is an equivalent circuit of a sensor cell of the solid-state image pickup device according to the embodiment of the invention.

FIG. 5 is a potential diagram in each mode of the solid-state image pickup device according to the embodiment of the invention.

FIG. 6 is a timing diagram showing a driving sequence according to the embodiment of the invention.

FIG. 7 is a timing diagram of a horizontal blanking period according to the embodiment of the invention.

### DESCRIPTION OF THE EMBODIMENT

An embodiment of the invention will now be described with reference to the accompanying drawings.

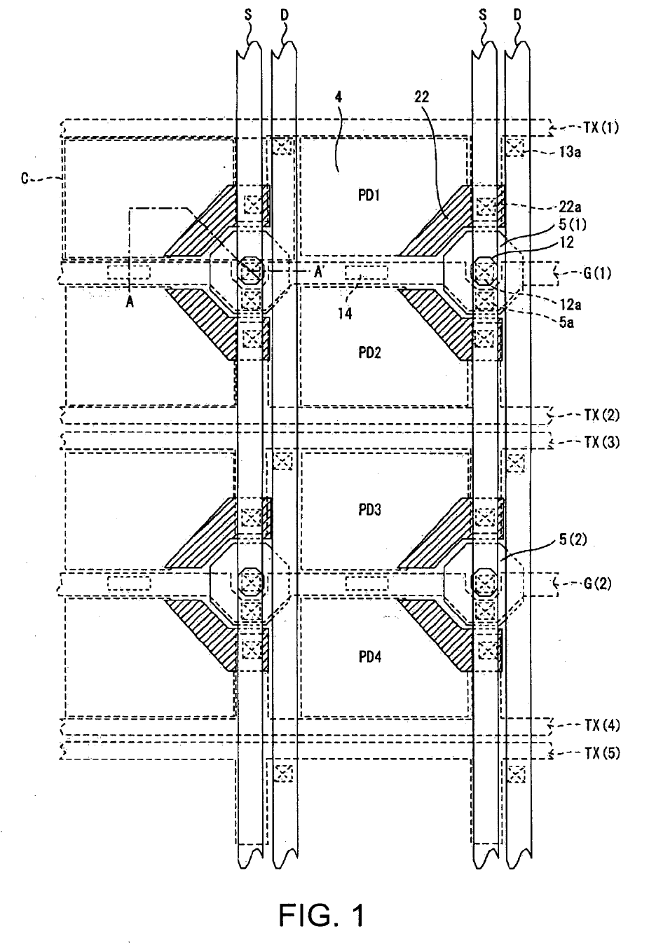

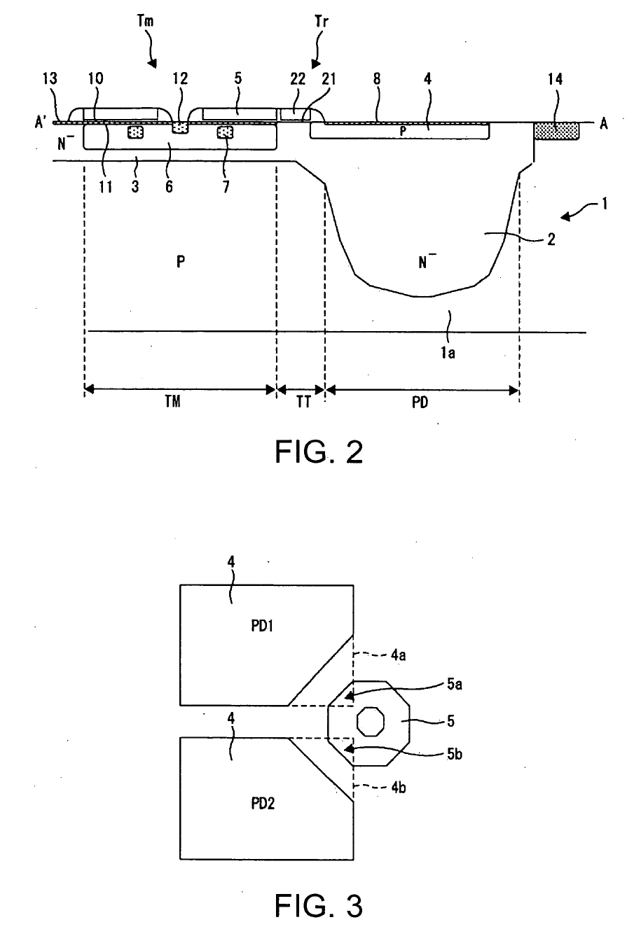

First, a structure of the solid-state image pickup device of the embodiment of the invention will be described. FIG. 1 is a plan view showing a planar configuration of a solid-state image pickup device according to the embodiment of the invention. FIG. 2 is a cross-sectional diagram taken along an A-A′ line of FIG. 1.

As shown in FIG. 1, the solid-state image pickup device of the embodiment is a censor cell array having a plurality of sensor cells arranged in a two-dimensional matrix on a flat surface of a substrate. Each sensor cell accumulates light-producing electric charge produced corresponding to incident light and outputs a pixel signal at a level based on the accumulated light-producing charge. The pixel signals for one image can be obtained by arranging the sensor cells in matrix. In FIG. 1, a region surrounded by dotted lines is a sensor cell C which is a unit pixel. Each sensor cell includes a photodiode formation region PD which is the photoelectric conversion region. The solid-state image pickup device of the embodiment is the substrate modulation type sensor. FIG. 1 shows eight of those sensor cells. Four out of the eight sensor cells are depicted as photodiode formation regions PD1 to PD4 (each photodiode formation region being hereinafter expressed as PD). Since all sensor cells have an identical structure, the photodiode formation region PD1 will be described in the following descriptions. Further, in the embodiment, electron holes are used as the light-producing electric charge. The same structure can apply when electrons are used as the light-producing electric charge.

As shown in FIG. 2, a modulation transistor formation region TM is provided in correspondence to the photodiode formation regions PD. Note that, as shown in FIG. 1, two photodiode formation regions PD are provided for one modulation transistor formation region TM. There are two transfer transistor formation regions TT between each of the photodiode formation region PD and the modulation transistor formation region TM in order to transfer the charge from each of the two photodiode formation regions PD to the single modulation transistor formation region TM.

In the embodiment, a transfer transistor Tr formed in the transfer transistor formation region TT is driven per each select line and transfers the charge (light-producing electric charge) accumulated in each of the photodiode formation regions PD to the modulation transistor formation region TM.

The structure of the solid-state image pickup device of the embodiment will be described in more detail with reference to FIGS. 1 and 2. As shown in FIG. 1, each of the plurality of photodiode formation regions PD arranged in matrix is in a shape of near rectangle. Also, there is a cut-off corner on each of the photodiode formation regions PD adjoined in pairs and arranged in a vertical direction, which is one of the directions of the two-dimensional matrix. These cut-off portions on the two adjoining photodiode formation regions PD lie next to each other.

FIG. 3 is a plan view to explain a positional relationship between the two adjoining photodiode formation regions PD1 and PD2 and a ring gate 5 (expressed as ring gate 5(1) in FIG. 1). As shown in FIG. 3, one ring gate 5 is interposed between the cut-off corners 4a and 4b of the pair of near-rectangular photodiode formation regions PD1 and PD2 adjoined in the vertical direction of the two-dimensional matrix.

In other words, when a substrate 1 is viewed from a direction perpendicular to the surface of the substrate, the ring gate 5 is disposed in a manner that portions 5a and 5b of the cut-off corners 4a and 4b of the photodiode formation regions PD1 and PD2, which are cut off from the two near-rectangular photodiode formation regions PD, overlap with the cut-off corners 4a and 4b. Also, the ring gate 5 is contained in the modulation transistor Tm formed in the modulation transistor formation region TM. Thus, one modulation transistor Tm is provided per each pair of adjoining photodiode formation regions PD arranged in one direction of the two-dimensional matrix.

The transfer transistor formation region TT is disposed between the photodiode formation regions PD and their corresponding modulation transistor formation region TM. A transfer gate 22 of a transfer transistor Tr of the transfer transistor formation region TT has a shape of a portion cut off from each corner of the photodiode formation region PD and a shape of a strip (octagonal shape in FIG. 1) formed along a circumferential shape of the ring gate 5. Further, the transfer gate 22 is disposed via a gate insulating film 21 on the surface of the substrate 1.

Further, as shown in FIG. 1, the transfer transistor Tr formed in the transfer transistor formation region TT is provided in every photodiode formation region PD. A pair of the transfer transistors Tr functions as the transfer control element that controls the transfer of the light-producing electric charge by changing the potential barrier of each transfer path of the light-producing electric charge between an accumulation well 4 of each corresponding pair of photodiode formation regions PD and one corresponding modulation well 6.

Therefore, because one ring gate is provided per two sensor cells, that is, per a pair of sensor cells, in one direction (the vertical direction in FIG. 1) of the two-dimensional matrix, two photodiode formation regions PD1 and PD2 share one ring gate 6(1) as shown in FIG. 1. The photodiode formation regions PD3 and PD4 next to the PD1 and PD2 share one ring gate 5(2). Hereinafter, such two sensor cells sharing one ring gate is called a pair of sensor cells. Accordingly, if there are lines of n rows (n being an integer) in a given direction of the two dimensions, such as in the vertical direction as in FIG. 1, n/2 ring gates are provided in this direction. Further, if the sensor cell array has n×m pixels in the matrix (m being an integer), the number of the ring gates 5 will be n/2×m.

The photodiode formation regions PD are formed between source lines S and drain lines D in the vertical direction of the two-dimensional matrix and between transfer gate lines TX(1), TX(2), TX(3), etc. (hereinafter, each transfer gate line may be expressed as TX) and gate lines G(1), G(2), G(3), etc. (each gate line may be hereinafter expressed as G) in a horizontal direction. More specifically, each pair of sensor cells C are disposed among the source lines S, drain lines D, and the transfer gate lines TX. In contrast, the plurality of gate lines G are provided so as to pass between the two photodiode formation regions PD of each pair of sensor cells C. Therefore, in the embodiment, in the vertical direction, the transfer gate lines TX(1) and TX(n) are each provided at each end of the vertical direction, and the transfer gate lines TX and the gate lines G are alternately arranged in pairs between both ends of the transfer gate lines.

As shown in FIG. 1, the transfer gate line TX(1) is disposed corresponding to the first row of the matrix containing the photodiode formation region PD1, and the transfer gate line TX(2) is disposed corresponding to the second row of the matrix containing the photodiode formation region PD2. In short, a transfer gate line TX(i) is disposed corresponding to the i-th row of the matrix containing a photodiode formation region PDi. Here, i is an integer from 1 to n. The transfer gate lines TX are each coupled to the plurality of transfer transistors Tr arranged in the horizontal direction of the two-dimensional matrix.

Further, the gate line G(i) is disposed corresponding to the first and second rows of the matrix containing the photodiode formation regions PD1 and PD2, and the gate line G(2) is disposed corresponding to the third and fourth rows of the matrix containing the photodiode formation regions PD3 and PD4. That is, a gate line G(k) is disposed corresponding to the (2k−1)th row and (2k)th row of the matrix containing the photodiode formation regions PD(2k−1) and PD(2k). Here, k indicates an integer of from 1 to n/2. In addition, the gate lines G(1), G(2), G(3), etc. are curved to be formed along the shape of the gate 5 having the ring-like shape (as described later).

As shown in FIG. 2, each sensor cell is formed on a P-type substrate 1a. On the P-type substrate 1a of the photodiode formation region PD, an N-doped N-type well 2 is formed at a deep position in the substrate. In contrast, on the P-type substrate 1a of the modulation transistor formation region TM, an N⁻doped N-type well 3 is formed at a relatively shallow position in the substrate. Additionally, the numbers of superscripts − and + of N and P used in FIG. 2 and in its descriptions indicate a degree of impurity density, from lower concentration impurity (superscripts −−) to higher concentration impurity (superscript ++.)

A P-type impurity layer is formed on an almost entire surface of the approximate photodiode formation region PD on the N-type well 2 of the photodiode formation region PD, and this P-type impurity layer functions as the accumulation well 4. On an almost entire surface on the substrate surface side of the photodiode formation region PD, an N⁺ diffusion layer 8 functioning as a pinning layer is formed. In the photodiode formation region PD, there are formed an opening region on the surface of the substrate 1 and the accumulation well 4 which is a P-type well wider than this opening region.

There is a depletion region formed in a bordering region between the N-type well 2 and the P-type accumulation well 2 which are formed on the substrate 1 at a lower part of the photodiode formation region PD that functions as a photoelectric conversion element. In this depletion region, the light-producing electric charge is generated by the incident light via the light-receiving opening region in the photodiode formation region PD. The generated light-producing electric charge is accumulated in the accumulation well 4.

As the modulation transistor Tm as an amplification means formed in the modulation transistor formation region TM, a depression mode N-channel MOS transistor is used, for example. On the N-type well 3 in the modulation transistor formation region TM, there is formed the gate (hereinafter called the ring gate or, simply, the gate) 5 having the ring-like shape (octagonal shape in FIGS. 1 and 3) via a gate insulating film 10 on the surface of the substrate 1. On the substrate surface below the ring gate 5, an N⁺ diffusion layer 11 composing the channel is formed. On the substrate surface in the center of an aperture of the ring gate 5, an N⁺⁺ diffusion layer is formed, thereby a source region (hereinafter may simply be called a source) 12 is formed. On the N-type well 3 of the modulation transistor formation region TM, the P-type impurity layer is formed along the near circumferential configuration of the ring gate 5 that composes the modulation transistor, and the P-type impurity layer functions as the modulation well 6. Inside this modulation well 6, there is formed a high-concentration P-type impurity region called a carrier pocket 7, which is a floating P⁺ diffusion region and is ring-shaped in compliance with the ring configuration of the ring gate 5.

Further, on the substrate surface surrounding the ring gate 5, the N⁺ diffusion layer is formed composing a drain region (hereinafter may simply be called a drain) 13. The N⁺ diffusion layer 11 composing the channel is coupled to the source region 12 and the drain region 13.

The modulation well 6 controls the threshold voltage of the channel of the modulation transistor Tm. The modulation transistor Tm is composed of the modulation well 6, the ring gate 5, the source region 12, and the drain region 13, and, thereby, the threshold voltage of the channel shifts corresponding to the charge accumulated in the carrier pocket 7.

Moreover, as shown in FIG. 1, a gate contact region 5a of the N⁺ layer is formed at a predetermined position in the ring gate 5 near the surface of the substrate 1. A source contact region 12a of the N⁺ layer is formed at a predetermined position in the source region 12 near the surface of the substrate 1. A drain contact region 13a of the N⁺ layer is formed at a predetermined position of the drain region 13 near the surface of the substrate 1.

The charge accumulated in the accumulation well 4 is then transferred to the modulation well 6 via the transfer transistor formation region TT, which will be described next, and is held in the carrier pocket 7. The source potential of the modulation transistor formation region TM that functions as the modulation transistor corresponds to a quantity of the charge transferred to the modulation well 6, that is, corresponds to the incident light applied to the photodiode formation region PD that functions as the photodiode.

On the surface of the substrate 1 near the accumulation well 4, a diffusion region (hereinafter called an overflow drain (OFD) region) 14 for discharging excess charge including overflowed charge is formed with a high concentration P⁺⁺ type diffusion layer. The OFD region 14, as a means for discharging the excess charge, is the region for discharging the excess charge that overflowed from the accumulation well 4 without being accumulated in the accumulation well 4 to the substrate and that is not used for the pixel signals. To include the OFD region 14 in the structure is advantageous in that, as will be described later, the excess charge generated between a noise-component readout timing and a signal-component readout timing is discharged through the OFD region 14 when the sensor cell is receiving light, for example, from a very high intensity subject. In this regard, if there is no OFD region, the excess charge is discharged via a transfer means to a modulation means and is discharged to the substrate during a reset operation in the readout period. Therefore, no problem arises in actuality, and choices can be made depending on the specification.

The transfer transistor formation region TT will be described. On the substrate surface side, the transfer transistor formation region TT is formed between the photodiode formation region PD and the modulation transistor formation region TM inside one sensor cell. The transfer transistor formation region TT includes the transfer gate 22 via the gate insulating film 21 on the substrate surface so that the channel is formed on the substrate surface. This channel in the transfer transistor formation region TT, that is, the transfer path, is controlled by voltages applied to the transfer gate 22.

Additionally, as shown in FIG. 1, a gate contact region 22a of the N⁺ layer is formed near the surface of the substrate 1 in the predetermined position of the transfer gate 22.

Further, on the substrate surface, a wiring layer including the described transfer gate lines TX(1), TX(2), TX(3), etc., the source lines S, and the like is formed via an interlayer insulating film which is not shown in the drawings. The transfer gate 22, the source contact region 12a, and the like are electrically coupled to each line of the wiring layer by contact holes made in the interlayer insulating film. Each line is composed, for example, of metal material such as aluminum.

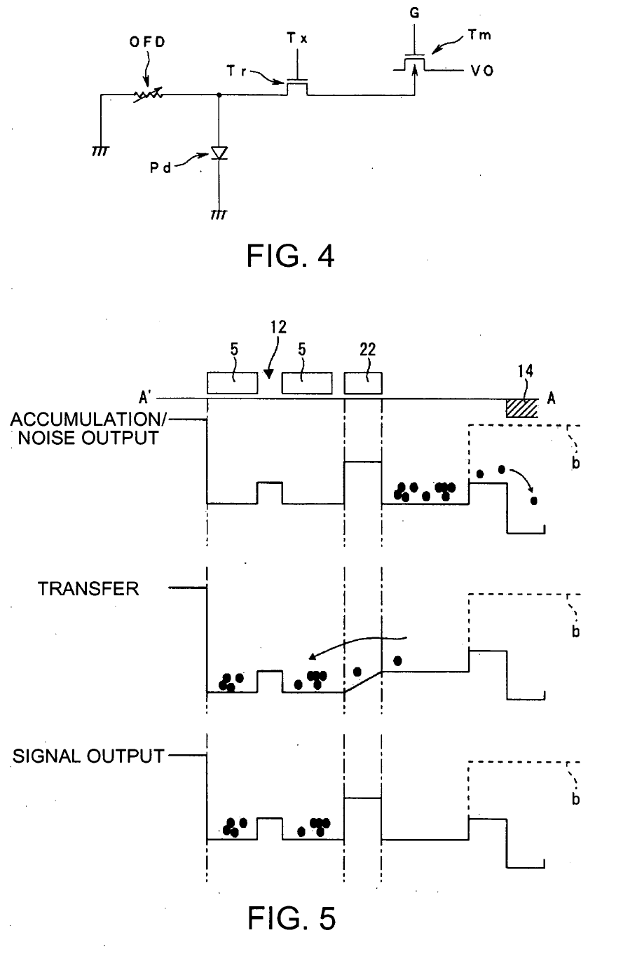

FIG. 4 is an equivalent circuit of the sensor cell of the solid-state image pickup device of the embodiment. The sensor cell C includes: a photodiode Pd formed in the photodiode formation region PD, the modulation transistor Tm formed in the modulation transistor formation region TM, and the transistor Tr as the transfer control element formed in the transfer transistor formation region TT.

The charge (the light-producing electric charge) generated by the photodiode Pd that carries out the photoelectric conversion is transferred to the carrier pocket 7 of the modulation transistor Tm by adjusting the voltage of the transfer gate 22 of the transistor Tr to be a predetermined voltage.

With the modulation transistor Tm, the charge held in the carrier pocket 7 becomes equivalent to the change in a back gate bias, and the threshold voltage of the channel shifts corresponding to the quantity of the potential in the carrier pocket 7. Consequently, an output voltage VO of the modulation transistor Tm is to correspond to the charge inside the carrier pocket 7, that is, to brightness of the incident light coming into the photodiode Pd.

Further, in FIG. 4, a variable resistance OFD coupled to one end of the photodiode Pd is shown. The OFD region 14 is represented by the variable-resistance OFD, since the OFD region 14 shifts the potential corresponding to the supplied potential.

FIG. 5 is a potential diagram showing a potential state in each mode of the solid-state image pickup device. FIG. 5 shows, from top to bottom, the potentials at an accumulation/noise output mode (M1), a transfer mode (M2), and a signal output mode (M3). Also, in FIG. 5, a relation of the potentials in each mode is shown, and a direction in which the potential of the electron holes becomes higher is the positive side.

FIG. 5 is a diagram showing the potential relation of each position, horizontally taken along the A-A′ line of FIG. 1 as similarly to FIG. 2, and, vertically, the potential is taken based on the holes. FIG. 5 shows, from left to right, the potential at one end of the ring gate 5, at the source region 12, at the other end of the ring gate 5, at the transfer gate 22 of the transfer transistor Tr, at the accumulation well 4, and inside the substrate at a position of the OFD region 14.

In the accumulation/noise mode (M1), a voltage is applied to the transfer gate 22 of the transfer transistor Tr between the accumulation well 4 and the carrier pocket 7 so that a high potential barrier is formed. The potential in the OFD region 14 is lower than the potential in the region of the transfer gate 22, so that the charge overflowed from the accumulation well 4 are discharged to the OFD region 14. More specifically, as an accumulation procedure, with all pixels simultaneously, the potential barrier of the transfer path is controlled by the gate voltage of the transfer transistor Tr, and the light-producing electric charge produced by the photoelectric conversion element are accumulated in the accumulation well 4 at least via the transfer path in a manner that the light-producing electric charge does not flow into the carrier pocket 7.

In this mode (M1), resetting and readout of the noise components are carried out as will be described later. That is, as a noise component modulation procedure, the noise components of the carrier pocket 7 are readout without letting the light-producing electric charge flow into the carrier pocket 7 by controlling the potential barrier of the transfer path using the gate voltage of the transfer transistor Tr.

In the transfer mode (M2) conducted per each row, a predetermined low voltage is applied to the transfer gate 22 of the transfer transistor Tr between the accumulation well 4 and the modulation well 6 in a manner that the potential barrier is not formed. In this case, because the potential of the modulation well 6 is lower than that of the accumulation well 4, the charge accumulated in the accumulation well 4 flows into the modulation well 6. That is, as a transfer procedure conducted per each row, the potential barrier of the transfer path is controlled by the gate voltage of the transfer transistor Tr, and, thereby, the light-producing electric charge accumulated in the accumulation well 4 is transferred to the carrier pocket 7.

In the signal output mode (M3), a voltage is applied to the transfer gate 22 of the transfer transistor Tr between the accumulation well 4 and the modulation well 6 so that the high potential barrier is formed. Consequently, the charge flowed into the modulation well 6 is held in the modulation well 6. Further, maintaining this state, the signal components are read out as will be described later. In other words, as the signal component modulation procedure, the potential barrier of the transfer path is controlled by the gate voltage of the transfer transistor Tr, and, while holding the light-producing electric charge in the modulation well 6, the pixel signals corresponding to the light-producing electric charge are output from the carrier pocket 7.

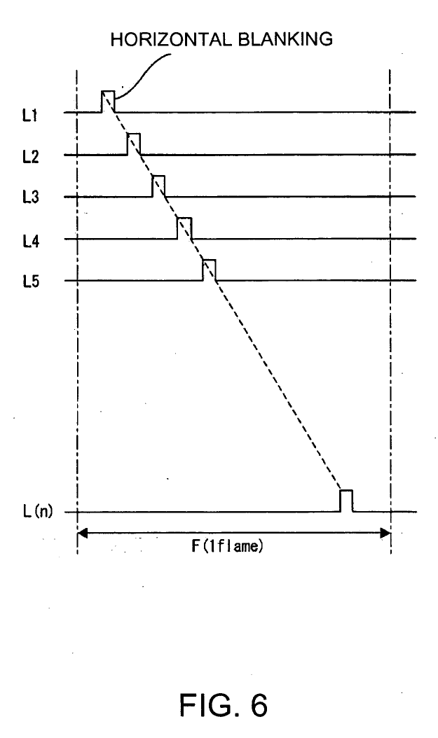

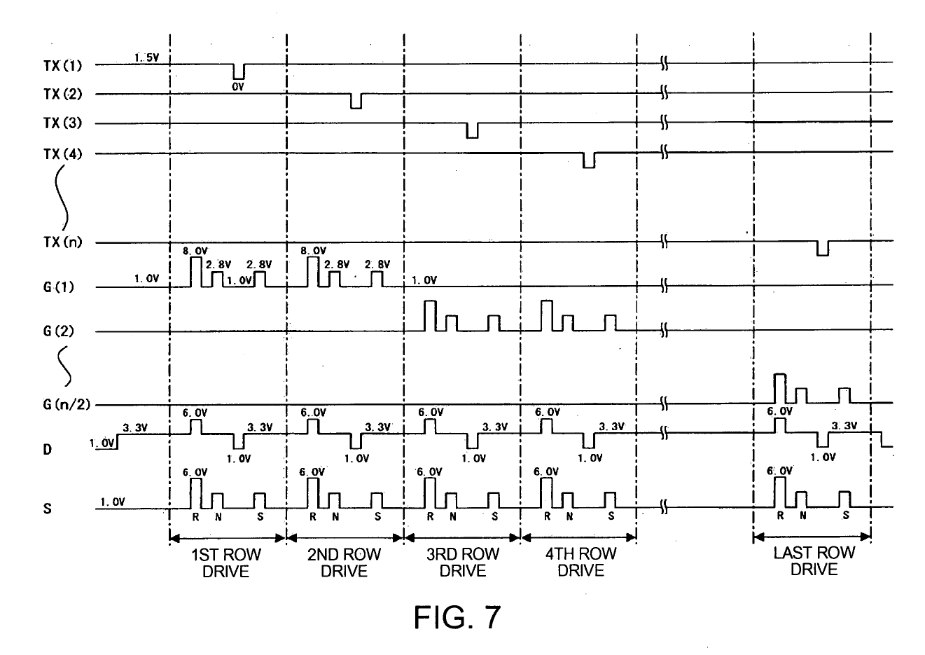

Next, the method for driving the solid-state image pickup device having the above-described structure will be described with reference to FIGS. 6 and 7 in accordance with an operational sequence.

FIG. 6 is a timing diagram showing the driving sequence of the solid-state image pickup device of the embodiment. As shown in FIG. 6, in a 1 frame period F, the pixel signals are read out row-sequentially from a first row L1 to an nth row Ln from the sensor cell array composed of the two-dimensional matrix having n rows. FIG. 6 shows that, when n is an even integer, the readout period, that is, a horizontal blanking period (H), is produced shifting time-sequentially from the first row having the photodiode formation region PD1 of FIG. 1 to the last nth row.

FIG. 7 is a timing diagram to explain the horizontal blanking period (H). The horizontal blanking period (H) occurs per select row. FIG. 7 shows waveforms of voltages applied to the transfer gate 22 of the transistor Tr, the gate 5 of the modulation transistor Tm, the source 12, and the drain 13 during the horizontal blanking period (H).

The transfer gate line TX(1) shown in FIG. 1 is coupled to the transfer gate 22 of the transfer transistor Tr in each cell in the first row. The transfer gate line TX(2) is coupled to the transfer gate 22 of the transfer transistor Tr in each cell in the second row. Similarly, the transfer gate line TX(n) is coupled to the transfer gate 22 of the transfer transistor Tr in each cell in the nth row.

Further, the gate line G(1) is coupled to the ring gate 5 of the modulation transistor Tm in each cell in the first and second rows. The gate line G(2) is coupled to the ring gate 5 of the modulation transistor Tm in each cell in the third and fourth rows. Similarly, the gate line G(k) is coupled to the ring gate 5 of the modulation transistor Tm in each cell in the (2k−1)th and (2k)th rows, with k being an integer of from 1 to n/2.

First, when reading out the pixel signals on the line of the first row, the voltage of each of the gate line G(1), the drain line D, and the source line S is first controlled as a reset operation, and all the charge inside the carrier pocket 7 of each modulation transistor Tm in the first row is discharged. More specifically, in this reset period, the voltage of the gate line G(1) shifts from 1.0V to 8V; the voltage of the drain line D shifts from 3.3V to 6.0V; and the voltage of the source line S shifts from 1.0V to 6.0V.

Next, as the readout operation of the noise components in the pixel signals in the first row, the voltage of each of the gate line G(1), the drain line D, and the source line S is controlled, and the noise components are read out based on the quantity of the charge remained in the carrier pocket 7 of each modulation transistor Tm in the first row. More specifically, in this noise component readout period, the voltage of the gate line G(1) shifts from 1.0V to 2.8V; the voltage of the drain line D is 3.3V; and the voltage of the noise component is output to the source line S.

Next, as the transfer operation for transferring the charge accumulated in the accumulation well 4 of the photodiode formation region PD to the carrier pocket 7, the voltage of each of the transfer gate line TX(1) and the drain line D is controlled, and, thereby, the charge accumulated in each of the accumulation wells 4 in the first row is transferred to the corresponding carrier pocket 7. More specifically, in this transfer operation period, the voltage of the transfer gate line TX(1) shifts from 1.5V to 0V; the voltage of the drain line D shifts from 3.3V to 1.0V; and the voltage of the source line S is 1.0V.

Thereafter, as the readout operation of the signal components in the pixel signals in the first row, the voltage of each of the gate line G(1) and the source line S is controlled, and the signal components are read out based on the quantity of the charge held in the carrier pocket 7 of each modulation transistor Tm in the first row. More specifically, in this signal component readout period, the voltage of the gate line G(1) shifts from 1.0V to 2.8V, and the voltage of the signal components is output to the source line S.

As thus described, the pixel signals in the first row are read out.

Next, the pixel signals readout operation on the lines of the second and third rows will be described. The two lines of the second and third rows are positioned between two gate lines G(1) and G(2), and two transfer gate lines TX(2) and TX(3) are positioned between the two lines of the. second and third rows.

The transfer gate line TX(2) is used to transfer the charge of each photodiode formation region PD in the second row to the carrier pocket 7 of each corresponding modulation transistor Tm. The transfer gate line TX(3) is used to transfer the charge of each photodiode formation region PD in the third row to the carrier pocket 7 of each corresponding modulation transistor Tm.

Also, the gate line G(1) is used to output the pixel signals corresponding to the charge from each photodiode formation region PD in the second row. The gate line G(2) is used to output the pixel signals corresponding to the charge from each photodiode formation region PD on the line of the third row.

Therefore, at first, as the reset operation when reading out the light-producing electric charge of each photodiode formation region PD in the second row, the voltage of each of the gate line G(1), the drain line D, and the source line S is controlled, and all the charge inside the carrier pocket 7 of each modulation transistor Tm in the second row is discharged. More specifically, in this reset period, the voltage of the gate line G(1) shifts from 1.0V to 8V; the voltage of the drain line D shifts from 3.3V to 6.0V; and the voltage of the source line S shifts from 1.0V to 6.0V.

Next, as the readout operation of the noise components in the pixel signals on the line of the second row, the voltage of each of the gate line G(1), the drain line D, and the source line S is controlled, and the noise components are read out based on the quantity of the charge remained in the carrier pocket 7 of each modulation transistor Tm in the second row. More specifically, in this noise component readout period, the voltage of the gate line G(1) shifts from 1.0V to 2.8V; the voltage of the drain line D is 3.3V; and the voltage of the noise component is output to the source line S.

Then, as the transfer operation for transferring the charge accumulated in the accumulation well 4 of the photodiode formation region PD to the carrier pocket 7, the voltage of each of the transfer gate line TX(2) and the drain line D is controlled, and the charge accumulated in each of the accumulation wells 4 in the second row is transferred to the corresponding carrier pocket 7. More specifically, in this transfer operation period, the voltage of the transfer gate line TX(2) shifts from 1.5V to 0V; the voltage of the drain line D shifts from 3.3V to 1.0V; and the voltage of the source line S is 1.0V.

Thereafter, as the readout operation of the signal components in the pixel signals on the line of the second row, the voltage of each of the gate line G(1) and the source line S is controlled, and the signal components are read out based on the quantity of the charge held in the carrier pocket 7 of each modulation transistor Tm in the second row. More specifically, in this signal component readout period, the voltage of the gate line G(1) shifts from 1.0V to 2.8V, and the voltage of the signal components are output to the source line S.

Next, as the reset operation when reading out the light-producing electric charge of each photodiode formation region PD on the line of the third row, the voltage of each of the gate line G(2), the drain line D, and the source line S is controlled, and the charge in the carrier pocket 7 of each modulation transistor Tm in the third row is discharged. More specifically, in this reset period, the voltage of the gate line G(2) shifts from 1.0V to 8V; the voltage of the drain line D shifts from 3.3V to 6.0V; and the voltage of the source line S shifts from 1.0V to 6.0V.

Next, as the readout operation of the noise components in the pixel signals on the line of the third row, the voltage of each of the gate line G(2), the drain line D, and the source line S is controlled, and the noise components are read out based on the quantity of the charge remained in the carrier pocket 7 of each modulation transistor Tm in the third row. More specifically, in this noise component readout period, the voltage of the gate line G(2) shifts from 1.0V to 2.8V; the voltage of the drain line D is 3.3V; and the voltage of the noise component is output to the source line S.

Then, as the transfer operation for transferring the charge accumulated in the accumulation well 4 of the photodiode formation region PD to the carrier pocket 7, the voltage of each of the transfer gate line TX(3) and the drain line D is controlled, and the charge accumulated in each of the accumulation wells 4 in the third row is transferred to the corresponding carrier pocket 7. More specifically, in this transfer operation period, the voltage of the transfer gate line TX(3) shifts from 1.5V to 0V; the voltage of the drain line D shifts from 3.3V to 1.0V; and the voltage of the source line S is 1.0V.

Thereafter, as the readout operation of the signal components in the pixel signals on the line of the third row, the voltage of each of the gate line G(2) and the source line S is controlled, and the signal components are read out based on the quantity of the charge held in the carrier pocket 7 of each modulation transistor Tm in the third row. More specifically, in this signal component readout period, the voltage of the gate line G(2) shifts from 1.0V to 2.8V, and the voltage of the signal components are output to the source line S.

As thus described, the pixel signals in the second and third rows are read out.

Next, similarly to the second and third rows, as the reset operation when reading out the light-producing electric charge of each photodiode formation region PD in the fourth row, the voltage of each of the gate line G(2), the drain line D, and the source line S is controlled, and all the charge inside the carrier pocket 7 of each modulation transistor Tm in the fourth row is discharged. More specifically, in this reset period, the voltage of the gate line G(2) shifts from 1.0V to 8V; the voltage of the drain line D shifts from 3.3V to 6.0V; and the voltage of the source line S shifts from 1.0V to 6.0V.

Next, as the readout operation of the noise components in the pixel signals on the line of the fourth row, the voltage of each of the gate line G(2), the drain line D, and the source line S is controlled, and the noise components are read out based on the quantity of the charge remained in the carrier pocket 7 of each modulation transistor Tm in the fourth row. More specifically, in this noise component readout period, the voltage of the gate line G(2) shifts from 1.0V to 2.8V; the voltage of the drain line D is 3.3V; and the voltage of the noise component is output to the source line S.

Then, as the transfer operation for transferring the charge accumulated in the accumulation well 4 of the photodiode formation region PD to the carrier pocket 7, the voltage of each of the transfer gate line TX(4) and the drain line D is controlled, and the charge accumulated in each of the accumulation wells 4 in the fourth row is transferred to the corresponding carrier pocket 7. More specifically, in this transfer operation period, the voltage of the transfer gate line TX(4) shifts from 1.5V to 0V; the voltage of the drain line D shifts from 3.3V to 1.0V; and the voltage of the source line S is 1.0V.

Thereafter, as the readout operation of the signal components in the pixel signals on the line of the fourth row, the voltage of each of the gate line G(2) and the source line S is controlled, and the signal components are read out based on the quantity of the charge held in the carrier pocket 7 of each modulation transistor Tm in the fourth row. More specifically, in this signal component readout period, the voltage of the gate line G(2) shifts from 1.0V to 2.8V, and the voltage of the signal components is output to the source line S.

As thus described, the pixel signals in the fourth row are read out.

On the lines from the fifth row and down, similarly to the described first to fourth rows, the same resetting, noise component readout, and signal component readout are conducted. Up to the nth row, which is the last row, the signal component readout and the like are also carried out.

As thus described, by controlling the voltage of the ring gate 5 disposed corresponding the pair of photodiode formation regions PD adjoined in one direction of the matrix, the noise components from the modulation transistor Tm and the signal components based on the transferred light-producing electric charge are read out. Further, by controlling the voltage of the transfer gate 22, the light-producing electric charge is transferred from one of the two accumulation wells 4 of the photodiode formation regions PD adjoined in one direction of the matrix to the modulation well 6.

As thus described, according to the solid-state image pickup device of the embodiment, one ring gate is provided per two photodiode formation regions PD, and, therefore, the cell pitch in the substrate modulation sensor can be narrowed. Further, because there is the transfer gate line provided in each row, the transfer control can be carried out independent of the two photodiode formation regions PD.

In addition, in the embodiment, although the OFD region 14 is provided on one surface of the substrate 1 near the accumulation well 4, the OFD region 14 may be omitted. If the OFD region 14 is omitted, the part corresponding to the OFD region 14 in the potential diagram shown in FIG. 5 will be as shown in dotted lines b.

The invention is not limited to the above-described embodiment, and various modifications, revisions, and the like can be made within the gist of the invention.

What is claimed is:

1. A solid-state image pickup device having inside a substrate a plurality of accumulation wells that accumulate light-producing electric charge produced in a photoelectric conversion region corresponding to light applied thereto, the plurality of photoelectric conversion regions being arranged in a two-dimensional matrix on the substrate, comprising:
a plurality of modulation transistors, each of which is provided in every pair of the photoelectric conversion regions adjoined in one direction of the two-dimensional matrix, which control a threshold voltage of a channel using the light-producing electric charge held in a modulation well, and which output a pixel signal corresponding to the light-producing electric charge;
a plurality of transfer control elements, each pair of which is provided in every pair of the adjoining photoelectric conversion regions, which shift a potential barrier of a path for transferring the light-producing electric charge between each accumulation well and the corresponding modulation well in the pair of photoelectric conversion regions, and which control the transfer of the light-producing electric charge; and
a plurality of transfer gate lines coupled to each of the transfer control elements in the plurality of photoelectric conversion regions arranged in the other direction of the two-dimensional matrix;
wherein each gate of the plurality of modulation transistors is in a ring-like shape, each gate being provided in a manner that at least a portion of the gate is interposed between partially cut-off portions of every pair of the approximately rectangular photoelectric conversion regions adjoined in one direction of the two-dimensional.

2. A method for driving the solid-state image pickup device having inside a substrate a plurality of accumulation wells that accumulate light-producing electric charge produced in a photoelectric conversion region corresponding to light applied thereto, the plurality of photoelectric conversion regions being arranged in a two-dimensional matrix on the substrate, including: a plurality of modulation transistors, each of which is provided in every pair of the photoelectric conversion regions adjoined in one direction of the two-dimensional matrix, which control a threshold voltage of a channel using the light-producing electric charge held in a modulation well, and which output a pixel signal corresponding to the light-producing electric charge; a plurality of transfer control elements, each pair of which is provided in every pair of the adjoining photoelectric conversion regions, which shift a potential barrier of a path for transferring the light-producing electric charge between each accumulation well and the corresponding modulation well in the pair of photoelectric conversion regions, and which control the transfer of the light-producing electric charge; and a plurality of transfer gate lines coupled to each of the transfer control elements in the plurality of photoelectric conversion regions arranged in the other direction of the two-dimensional matrix; wherein each gate of the plurality of modulation transistors is in a ring-like shape, each gate being provided in a manner that at least a portion of the gate is interposed between partially cut-off portions of every pair of the approximately rectangular photoelectric conversion regions adjoined in one direction of the two-dimensional, comprising:
firstly reading out a noise component from the modulation transistor by controlling a voltage of the gate provided corresponding to the pair of photoelectric conversion regions in one direction of the matrix;
transferring the light-producing electric charge from one of the two accumulation wells in the pair of photoelectric conversion regions to the modulation well in one direction of the matrix; and
secondly reading out a signal component from the modulation transistor based on the transferred light-producing electric charge by controlling a voltage of the gate provided corresponding to the pair of photoelectric conversion regions in one direction of the matrix.
